(19) United States
(12) Patent Application Publication
(10) Pub. No.: US 2004/0129200 A1
(43) Pub. Date: Jul. 8, 2004

(54) Active electronic devices based on gallium nitride and its alloys grown on silicon substrates with buffer layers of SiCAIN

(76) Inventors: John Kouvetakis, Mesa, AZ (US); Ignatius S.T. Tsong, Tempe, AZ (US); Radek Roucka, Tempe, AZ (US); John Tolle, Gilbert, AZ (US)

Correspondence Address: FENNEMORE CRAIG, 3003 NORTH CENTRAL AVENUE, SUITE 2600, PHOENIX, AZ, 85012, US

(21) Appl. No.: 10/663,168

(22) Filed: Sep. 15, 2003

Related U.S. Application Data
(63) Continuation-in-part of application No. 09/981,024, filed on Oct. 16, 2001.
Application No. 09/981,024 is a continuation-in-part of application No. 09/965,022, filed on Sep. 26, 2001, now abandoned.
(60) Provisional application No. 60/410,859, filed on Sep. 13, 2002.

(30) Foreign Application Priority Data
Oct. 16, 2002 (WO) PCT/US02/33134

(51) Int. Cl. C30B 1/00

(52) U.S. Cl. 117/2

(57) ABSTRACT

A semiconductor structure integrates wide bandgap semiconductors with silicon. The semiconductor structure includes: a substrate; a SiCAlN region formed over the substrate, and an active region formed over the SiCAlN region. The substrate can comprise silicon, silicon carbide (SiC) or silicon germanium (SiGe). The active region can include a gallium nitride material region, such as GaN, AlGaN, InGaN or AlInGaN. It also can include AlN and InN region. The structure also can include a crystalline oxide interface formed between the substrate and the SiCAlN region. A preferred crystalline oxide interface is Si—Al—O—N. The active layer can be formed by known fabrication processes, including metal organic chemical vapor deposition or by atomic layer epitaxy. The crystalline oxide interface is normally formed by growing SiCAlN on Si(111) via a crystalline oxide interface, but can also be formed by metal organic chemical vapor deposition or by atomic layer epitaxy.

### RELATED APPLICATIONS

This application is related to the following commonly assigned patent applications:

1. U.S. patent application Ser. No. 09/965,022, filed Sep. 26, 2001 in the names of Ignatius S. T. Tsong, John Kouvetakis, Radek Rouka and John Tolle, entitled “Low Temperature Epitaxial Growth of Quaternary Wide Bandgap Semiconductors.”

2. U.S. patent application Ser. No. 09/981,024, filed Oct. 16, 2001 in the names of Ignatius S. T. Tsong, John Kouvetakis, Radek Rouka and John Toll, entitled “Low Temperature Epitaxial Growth of Quaternary Wide Bandgap Semiconductors,” which is a continuation-in-part of U.S. patent application Ser. No. 09/965,022, filed Sep. 26, 2001. The present application is a continuation-in-part of U.S. patent application Ser. No. 09/981,024.

3. Provisional application serial No. 60/380,998, filed May 16, 2002, in the names of Ignatius S. T. Tsong, John Kouvetakis, Radek Rouka and John Tolle entitled “Growth of SiCAlN on Si (111) via a Crystalline Oxide Interface.”

4. U.S. Provisional Patent Application No. 60/410,859, filed Sep. 13, 2002, entitled “Active Electronic Devices Based on Gallium Nitride and Its Alloys Grown on Silicon Substrates with Buffer Layers of SiCAlN.” The present application claims the benefit of U.S. Provisional Patent Application No. 60/410,859.

5. PCT International Patent Application No. PCT/US02/33134, filed Oct. 16, 2002, entitled “Low Temperature Epitaxial Growth of Quaternary Wide Bandgap Semiconductors.” The present application claims priority benefits of PCT International Patent Application No. PCT/US02/33134.

Each of the aforementioned applications is incorporated herein by reference it its entirety.

### STATEMENT OF GOVERNMENT FUNDING

The United States Government provided financial assistance for this project through the United States Army Research Office, under Grant No. DAAD19-00-1-0471, and through the National Science Foundation under Grant No. DMR-9986271. Therefore, the United States Government may own certain rights to this invention.

### BACKGROUND

This invention relates generally to semiconductor materials and, more particularly, to semiconductor structures including gallium nitride materials formed on silicon substrates with a buffer layer of SiCAlN.

Gallium nitride materials include gallium nitride (GaN) and its alloys such as aluminum gallium nitride (AlGaN), indium gallium nitride (InGaN), and aluminum indium gallium nitride (AlInGaN). These materials are semiconductor compounds that have a relatively wide, direct bandgap, which permits highly energetic electronic transitions to occur. Such electronic transitions can result in gallium nitride materials having a number of attractive properties including the ability to efficiently emit blue and ultraviolet light, the ability to transmit signals at high frequency, and others. Accordingly, gallium nitride materials are being widely investigated in many semiconductor device applications, including microelectronic devices such as transistors, and optoelectronic devices such as laser diodes (LDs) and light emitting diodes (LEDs).

Gallium nitride materials have been formed on a number of different substrates including sapphire, silicon (Si), and silicon carbide (SiC). Device structures, such as doped regions, may then be formed within the gallium nitride material region. Previously, however, semiconductor structures having GaN formed on Si substrates have been extremely complicated and expensive to fabricate.

It is an object of the present invention, therefore, to provide semiconductor structures, including gallium nitride materials formed on silicon substrates, that are less complicated and expensive to fabricate and can be used for active semiconductor devices, such as transistors, field emitters, and optoelectronic devices.

### SUMMARY

In accordance with the invention, there is provided a semiconductor structure that integrates wide bandgap semiconductors with silicon. The semiconductor structure includes: a substrate; a SiCAlN region formed over the substrate, and an active region formed over the SiCAlN region. The substrate can comprise silicon, silicon carbide (SiC) or silicon germanium (SiGe). The active region can include a gallium nitride material region, such as GaN, AlGaN, InGaN or AlInGaN. It also can include AlN and InN region. The structure also can include a crystalline oxide interface formed between the substrate and the SiCAlN region. A preferred crystalline oxide interface is Si—Al—O—N. The active layer can be formed by known fabrication processes, including metal organic chemical vapor deposition or by atomic layer epitaxy. The crystalline oxide interface is normally formed by growing SiCAlN on Si(111) via a crystalline oxide interface, but can also be formed by metal organic chemical vapor deposition or by atomic layer epitaxy.

The semiconductor structure according to the invention can be used to fabricate active microelectronic devices, such as transistors including field effect transistors and bipolar transistors. The semiconductor structure also can be used to fabricate optoelectronic devices, such as laser diodes and light emitting diodes.

### BRIEF DESCRIPTION OF THE DRAWINGS

The accompanying drawings, which are incorporated in and constitute a part of the specification, illustrate the presently preferred embodiments and methods of the invention. Together with the general description given above and the detailed description of the preferred embodiments and methods given below, they serve to explain the principles of the invention.

FIG. 1 is a high-resolution cross-sectional transmission electron microscopy (XTEM) image of an epitaxial SiCAlN film grown on α-Si(0001), which film can be used to form a semiconductor structure according to the present invention.

FIG. 2 is an X-ray rocking curve of an on-axis SiCAlN(0002) peak of the SiCAlN film illustrated in FIG. 1.

FIG. 3 is an XTEM image showing columnar growth of a SiCAlN film grown on Si(111) according to the invention.

FIG. 4 is an XTEM image of a SiCAlN film grown on Si(111) illstrating the columnar grains.

FIG. 5 is an XTEM image of a SiCAlN film grown on Si(111) llustrating the characteristic . . . ABAB . . . stacking of the 2H-wurtzite structure of the film.

FIG. 6 illustrates a proposed model of the SiCAlN wurtzite structure showing a side view of SiCAlN atomic structure.

FIG. 7 illustrates a proposed model of the SiCAlN wurtzite structure of FIG. 6 showing a top view of the structure.

FIG. 8 is an XTEM image of a GeCAlN film grown on 6H—SiC (0001) substrate showing epitaxial interface and Ge precipitate.

FIG. 9 is an XTEM image of GeCAlN film grown on a Si(111) substrate showing a crystalline film with Ge precipitate.

FIG. 10 is an XTEM image of GeCAlN film grown on a Si(111) substrate showing the transition from cubic Si(111) to hexagonal structure of the film at the interface.

FIG. 11 is a Rutherford backscattering (RBS) spectrum of SiCAlN film grown at 725° C., which can be used to form a semiconductor structure according to the present invention. The inset shows the C resonance peak. The RBS simulations giving the atomic compositions of Si, Al, C and N are shown in dashed curves.

FIG. 12 is the Fourier transform infrared spectroscopy (FTIR) spectrum of a SiCAlN film that can be used to form a semiconductor structure according to the present invention.

FIG. 13 is an electron energy loss spectroscopy (EELS) elemental profile scan of Si, Al, C and N sampled across 35 nm over a SiCAlN film.

FIG. 14 is an XTEM image showing as a white line the region where the 35 nm scan of FIG. 13 took place on the film.

FIG. 15 illustrates an EELS spectrum showing the K-shell ionization edges of C and N characteristic of sp³ hybridization of these elements in the SiCAlN film.

FIG. 16 is an atomic force microscopy (AFM) image (at Rms: 13.39 nm Ra: 2.84 nm) showing the surface morphology of a SiCAlN film grown on SiC(0001)

FIG. 17 is a higher magnification AFM image of the same surface as FIG. 16.

FIG. 18 is a diagrammatic illustration of a basic semiconductor structure comprising the quaternary film semiconductor and a buffer layer on a silicon substrate.

FIG. 19 is a low-resolution XTEM image of a silicon oxynitride interface showing the oxide buffer layer as a thin band of dark contrast adjacent to the interface, as well as the SiCAlN grown above the oxide layer. The arrow indicates the location of the EELS line scan.

FIG. 20 is an EELS compositional profile showing the elemental distribution at the siliconoxynitride interface.

FIG. 21 is a structural model illustrating the transition of the silicon oxynitride interface structure from silica to SiCAlN through an intermediate Si₃Al₆O₁₂N₂ framework of a sheet-like structure.

FIG. 22 is a high resolution XTEM of the siliconoxynitride interface showing the converted crystalline oxide buffer layer at the interface. The 2H structure of the SiCAlN is also clearly visible in the upper portion of the film.

FIG. 23 is a diagrammatic illustration of a semiconductor structure having an upper layer of Group III nitride grown on a substrate of SiCAlN or like material.

FIG. 24 shows an exemplary embodiment of an AlGaN/GaN heterostructure field effect transistor (HFET) in accordance with the present invention.

FIG. 25 shows an example of an InGaN/GaN heterojunction bipolar transistor (HBT) structure in accordance with the present invention.

FIG. 26 shows an example of a laser structure on a SiCAlN/Si(111) substrate in accordance with the present invention.

FIG. 27 shows an example of a GaInN MQW laser diode structure on a SiCAlN/Si(111) substrate in accordance with the present invention.

FIG. 28 shows an example of a UV LED structure on a SiCAlN/Si(111) substrate in accordance with the present invention.

### DESCRIPTION

Reference will now be made in more detail to the presently preferred embodiments and methods of the invention as illustrated in the accompanying drawings. While the present invention will be described more fully hereinafter with reference to these examples and accompanying drawings, in which aspects of the preferred manner of practicing the present invention are shown, it is to be understood at the outset of the description which follows that persons of skill in the appropriate arts may modify the invention herein described while still achieving the favorable results of this invention. Accordingly, the description which follows is to be understood as being a broad, teaching disclosure directed to persons of skill in the appropriate arts, and not as limiting upon the present invention.

We have developed a novel low temperature method for growing epitaxial quaternary thin films having the general formulae XCZN wherein X is a Group IV element and Z is a Group III element in a gas source molecular beam epitaxial chamber utilizing gaseous precursors having a structure comprising X—C—N bonds. As described herein, such films can be used to provide semiconductor structures that integrate wide bandgap semiconductors with silicon.

An “epitaxial” film generally refers to a film with the highest order of perfection in crystallinity, i.e. as in a single crystal. Because of their low defect density, epitaxial films are especially suitable for microelectronic and, more particularly, optoelectronic applications. The epitaxial growth of unimolecular films is generally achieved in a molecular beam epitaxy (MBE) apparatus. In molecular beam epitaxy (MBE), molecular beams are directed at a heated substrate where reaction and epitaxial film growth occurs. The technology is fully described in E. H. C. Parker (Ed.) “The Technology and Physics of Molecular Beam Epitaxy,” Plenum Press (1985) [7]. By selecting the appropriate flux species in MBE, and by exercising precise control of the kinetic factors, i.e., flux rate, flux ratio, and substrate temperature, during growth, the morphology, composition and microstructure of films can be tailored on an atomic level.

In the present method for growing epitaxial thin films, deposition of epitaxial film conforms to a variation of gas-source molecular beam epitaxy (GSMBE) which comprises a flux of a gaseous precursor and a vapor flux of metal atoms directed onto a substrate where the precursor reacts with the metal atoms to commence growth of epitaxial thin film on the substrate. Typically, the gaseous precursor is connected via a high vacuum valve to the GSMBE chamber (which will be known henceforth as a MBE reaction chamber) containing a heated substrate. Also installed in the MBE reaction chamber is a gas effusion Knudsen cell containing metal atoms. Sources of other vapor flux atoms may also be installed in the chamber. The gaseous precursor is allowed to flow into the reaction chamber, which is typically maintained at a base pressure of about 10⁻¹⁰ Torr by an ultrahigh vacuum pumping system.

The film growth process is conducted in the MBE chamber with the substrate held at temperatures between ambient temperature and 1000° C., preferably in the range of 550° C. to 750° C., with flux species consisting of a unimolecular gas-source precursor and elemental atoms from one or more effusion cells. The precursor provides the “backbone” or chemical structure upon which the quaternary compound builds. The substrates are preferably silicon or silicon carbide wafers. In the method, the substrate, growth temperature, flux species and flux rate may be chosen to determine various features of the quaternary film undergoing growth.

The present method for growing epitaxial thin films for semiconductor structures is based on thermally activated reactions between the unimolecular precursor and metal atoms, Z. The molecular structure of the precursor consists of a linear X—C—N skeleton with the target stoichiometry and direct X—C bonds that favor low-temperature synthesis of the thin film. Any remaining H—X terminal bonds are relatively weak and are eliminated as gaseous H₂ byproducts at low temperatures, making a contamination-free product. The unsaturated and highly electron-rich N site of the C—N moiety has the required reactivity to spontaneously combine with the electron-deficient metal atoms (Z) to form the necessary Z-N bonding arrangements without any additional activation steps.

Gaseous flux of unimolecular precursor having the formula H₃XCN in vapor form wherein X is a Group IV element, preferably silicon or germanium and H is hydrogen or deuterium, is introduced into a GSMBE chamber. A vapor flux of Z atoms, wherein Z is a Group III metal, is also introduced into the chamber from an effusion cell. Pressure and other conditions in the chamber are maintained to allow the precursor and the Z atoms to combine and form epitaxial XCZN on the substrate. Temperature of the substrate during the reaction is maintained at a value above ambient and less than 1000° C., considerably below the temperature of the miscibility gap of SiC and AlN phases at 1900° C. [6]. Most preferably the temperature is maintained between about 550° C. to 750° C.

In an important aspect of the method, a precursor compound having the formula H₃XCN wherein X is a Group IV element, preferably silicon (Si) or germanium (Ge) and wherein H is hydrogen or deuterium, is provided. The precursor H₃SiCN may be synthesized in a single-step process by a direct combination reaction of SiH₃Br and AgCN. Other suitable methods for preparation of H₃SiCN are known in the art. See, e.g., the method reported by A. G McDiarmid in “Pseudohalogen derivatives of monosilane” Inorganic and Nuclear Chemistry, 1956, 2, 88-94) [12] which involves the reactions of SiH₃I and AgCN. H₃SiCN is a stable and highly volatile solid with a vapor pressure of 300 Torr at 22° C., well suited for the MBE film-growth process. For preparation of quaternary XCZN wherein X is germanium, the precursor D₃GeCN is provided. In these instances, deuterium replaces hydrogen in the precursor to achieve better kinetic stability. The unimolecular precursor GeD₃CN may be synthesized using a direct reaction of GeD₃Cl with AgCN. Other methods for preparation of GeD₃CN utilize GeD₃I as the source of GeD₃ as disclosed in “Infrared spectra and structure of germyl cyanide” T. D. Goldfarb, The Journal of Chemical Physics 1962, 37, 642-646. [13].

In certain instances of the method, the flux rate of metal atom (Z) and precursor are maintained at a rate that provides an essentially equimolar amount of precursor and metal atom to the surface of the substrate i.e., the number of precursor molecules arriving at the substrate surface is the same as the number of metal atoms from the Knudsen effusion cell. In these instances, the quaternary semiconductor that is formed is essentially stoichiometric XCZN and will have the formula (XC)_{(0.5-a)}(ZN)_{(0.5+a)} wherein X is a Group IV element and Z is a Group III element and a is essentially zero.

In certain other instances of the method, the stoichiometry of the quaternary compound may be changed by increasing the amount of ZN component. In these instances, extra N-atoms which may be generated by methods known in the art, preferably from a radio frequency (RF) plasma source (also mounted in the MBE chamber) are supplied and the metal (Z) atom flux is increased slightly. The ZN content of the quaternary compound is thus increased to more than 50%, i.e., a>0, as metal atoms Z combine with N in the X—C—N precursor and also with the gaseous N-atoms to form additional ZN. Correspondingly, the XC content will become less than 50%, i.e. drop to 0.5-a, because XC+ZN=100%. In these instances, the resultant semiconductor will have the formula (XC)_{(0.5-a)}(ZN)_{(0.5+a)} wherein X is a Group IV element and Z is a Group III element and a is between 0 and 0.5.

The bandgap of the semiconductors may be adjusted by varying the deposition parameters to create a series of (XC)_{0.5-a}(ZN)_{(0.5}+a) films with different values of a. The bandgap of the quaternary film will reflect the relative concentrations, or stoichiometry of the two components. The composition of the film, i.e. the value of a, can be adjusted by supplying excess C as from CH₄ gas or N as N-atoms from a radio-frequency plasma source. In certain instances, for example when the XC component of the quaternary compound has a different band gap from the ZN component, the flux ratio of precursor, metal atoms and nitrogen atoms may be controlled to increase the amount of ZN in the film and to provide a quaternary film having the desired bandgap.

The bandgap can also be adjusted by changing the constituents, for example, from SiC to GeC or SnC (with calculated bandgaps of 1.6 eV and 0.75 eV respectively). In these instances, the formula of the quaternary compounds will be (XC)_{(0.5-a)}(ZN)_{(0.5+a)} wherein X and Z are independently the same or different in each occurrence. Thus a complete series of solid solutions between Group IV carbides and Group III nitrides can be synthesized via the present method to provide semiconductors with bandgaps ranging from 2 eV to 6 eV, covering a spectral range from infrared to ultraviolet, ideal for a variety of optoelectronic applications. Examples of related novel systems include SiCGaN, SiCInN, GeCGaN, SnCInN and GeCInN.

In preferred methods, the XCZN quaternary films are grown on semiconductor substrates, preferably Si(111) or α-SiC(0001). Si(100) and Si wafers of other orientations or other material structures may also be used as substrates. The wafers may be cleaned prior to deposition or may comprise buffer layers of oxide or other buffer layers such as Group II nitride, preferably aluminum nitride.

In an important aspect of the invention, the deposited XCZN thin film is a substrate for growth of other compounds by methods generally employed in the industry for semiconductor fabrication. Group III nitrides, preferably aluminum nitride, for example, may be grown on SiCAlN thin films prepared by the present method. XCZN films formed on large area wafers comprising Si or SiC are especially suitable for substrates for growth of the Group III nitride layers. This is illustrated diagrammatically in FIG. 23 where 10 is the Si wafer on which the XCZN film 12 is formed and 14 represents a growth of Group III nitride.

Semiconductor quaternary XCZN grown in accordance with the method of the present invention may be doped in order to achieve p-type or n-type material by methods known in the art. The as-deposited SiCAlN films, e.g., are generally of n-type intrinsically. To render the film p-type, dopants known in the art, such as Mg, for example, may be used.

The hardness of the films prepared by the present method, defined as the applied load divided by the indented surface area, was measured using a nano-indentor (Hysitron Triboscope) attached to an atomic force microscope (AFM). Using the hardness value of 9 GPa measured for fused silica as a standard, the nano-indentation experiments yielded an average hardness of 25 GPa for the SiCAlN films, close to that measured for sapphire under the same conditions. The films deposited on silicon substrates are characterized to be true solid solutions of SiC and AlN with a 2H wurtzite structure. The hardness of these films is comparable to that of sapphire. The boron analogues, XCBN are anticipated to be especially suitable as superhard (e.g., 20 GPa or higher) coatings because of the hardness values of the individual binary components.

The present method refers generally to epitaxial growth of nanostructures of quaternary semiconductors on substrate surfaces. Different features of the film surface can be enhanced, e.g., topography, chemical differences, or work function variations. Thus, in addition to films, quantum wells and quantum dots can be fabricated according to the present method.

Superlattice or quantum well structures comprising epitaxial XCZN films of the present invention define a class of semiconductor devices useful in a wide variety of optoelectronic and microelectronic applications. Such devices are useful in high-frequency, high-power, and high-temperature applications including applications for radiation-resistant use. Exemplary of the devices incorporating the wide bandgap semiconductors of the present invention are light-emitting diodes (LED) and laser diodes (LD). Generally, a LED comprises a substrate, α-SiC(0001), Si(111) or Si(111) with AlN buffer layer, and a multi-layer quantum well structure formed on the substrate with an active layer for light emission. In the present instance, the active layer can comprise an (XC)_{(0.5-a)}(ZN)_{(0.5+a)} (where 0<a<0.5) layer that is lattice-matched with the substrate and prepared by the method of the present invention. Single-phase epitaxial films of a stoichiometric SiCAlN grown at 750° C. on 6H—SiC(001) and Si(111) substrates is wide bandgap semiconductor exhibiting luminescence at 390 nm (3.2 eV) consistent with the theoretical predicted fundamental bandgap of 3.2 eV (15, 22).

Also exemplary of the optoelectronic devices incorporating the present semiconductors are negative electron affinity cathodes for field emission flat-panel displays, high-frequency, high-power, and high-temperature semiconductor devices, UV detectors and sensors.

A large variety of microelectronic and optoelectronic devices comprising semiconductor devices and layered semiconductor structures of the present invention can be provided.

### EXPERIMENTAL FILMS

Epitaxial XCZN Films Grown on SiC

Epitaxial SiCAlN films were grown in a MBE chamber according to the present method from the gaseous precursor H₃SiCN and Al atoms from an Knudsen effusion cell supplied to the chamber directly on 6H—SiC (0001) wafer as substrate with the substrate temperature in the region of 550° C. to 750° C.

In this instance, the α-SiC (0001) wafers were cleaned and surface scratches removed using a process described in U.S. Pat. No. 6,306,675 issued to I. S. T. Tsong et al. for “Method for forming a low-defect epitaxial layer in the fabrication of semiconductor devices,” herein incorporated by reference. The base pressure in the MBE chamber was about 2×10⁻¹⁰ Torr, rising to about 5×10⁻⁷ Torr during deposition. The flux rate of each species was set at about 6×10¹³ cm⁻²s⁻¹, giving a H₃SiCN:Al flux ratio of ˜1 and a growth rate at 700-750° C. of ˜4 nm min⁻¹. Films with thickness 130-150 nm were deposited. The deposited films had a transparent appearance as expected for a wide bandgap material.

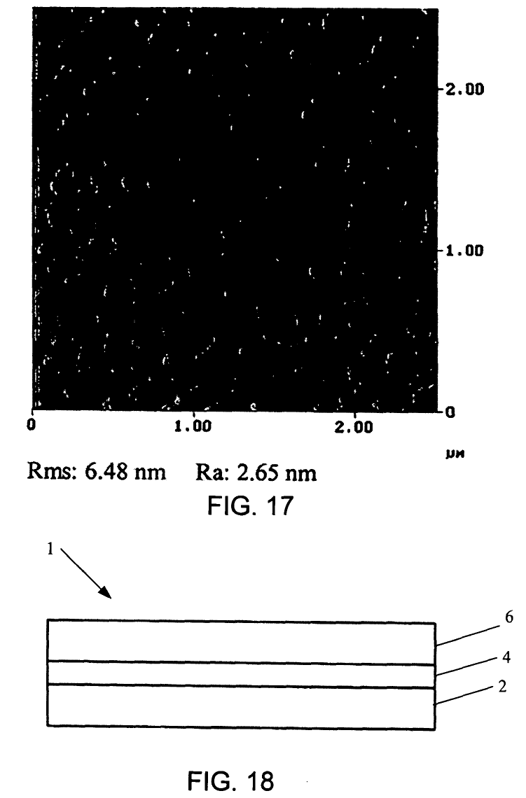

On the SiC substrates, the epitaxial film shows an ordered hexagonal structure comprising 2H/2H and 4H/2H polytypes² [15]. FIG. 16 is an atomic force microscopy (AFM) image (at Rms: 13.39 nm, Ra: 2.84 nm) showing the surface morphology of a SiCAlN film grown on SiC(0001). FIG. 17 is a higher magnification AFM image of the same surface as FIG. 16.

Epitaxial XCZN Films Grown on Clean Si(111)

Growth on clean Si(111)-(7×7) substrates, in contrast to the SiC(001) wafers, resulted in inhomogeneous films with a rough surface morphology. TEM studies revealed a microstructure dominated by randomly oriented polycrystalline grains with no significant registry with the underlying Si substrate.

Because of the elimination of the native SiO₂ layer when a crystalline SiCAlN film is grown on a Si(111) substrate, the process of depositing SiCAlN on a large-diameter Si(111) wafer produces a large-area substrate lattice-matched for growth of Group III binary or ternary nitrides such as GaN, AlN, InN, AlGaN and InGaN. “Large-diameter wafers” is a term used in the art to designate wafers larger than about 2 inches.

Epitaxial SiCAlN Films Grown on Si(I 1) Having a Native Oxide Layer (˜1 nm)

SiCAlN was deposited by the present method on Si (111) crystals having an intact native oxide layer. In this instance, epitaxial SiCAlN films were grown in a conventional MBE chamber according to the present method, as described hereinabove, directly on Si(111) wafer as substrate with the substrate temperature in the region of 550° C.-750° C.

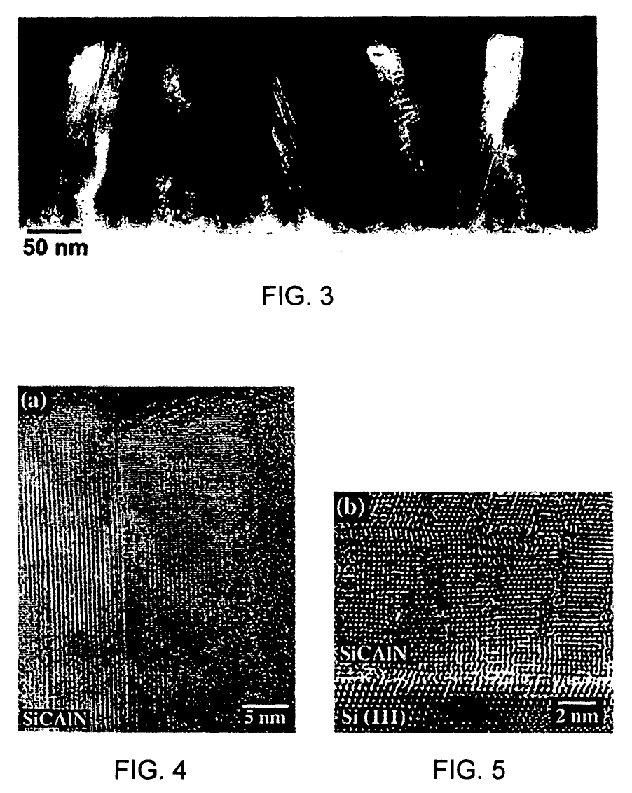

The microstructure of the films is revealed by a typical XTEM image of the SiCAlN film on Si (111) shown in FIGS. 3, 4 and 5. Columnar grains 25-30 nm wide extending from the film/substrate interface through the entire layer are illustrated by the XTEM image shown in FIGS. 3 and 4. FIG. 3 shows columnar growth of SiCAlN film grown on Si(111), the columns being well-aligned with predominantly basal-plane growth. The randomness in the orientation of the crystallographic planes in the columns are visible in FIG. 3.

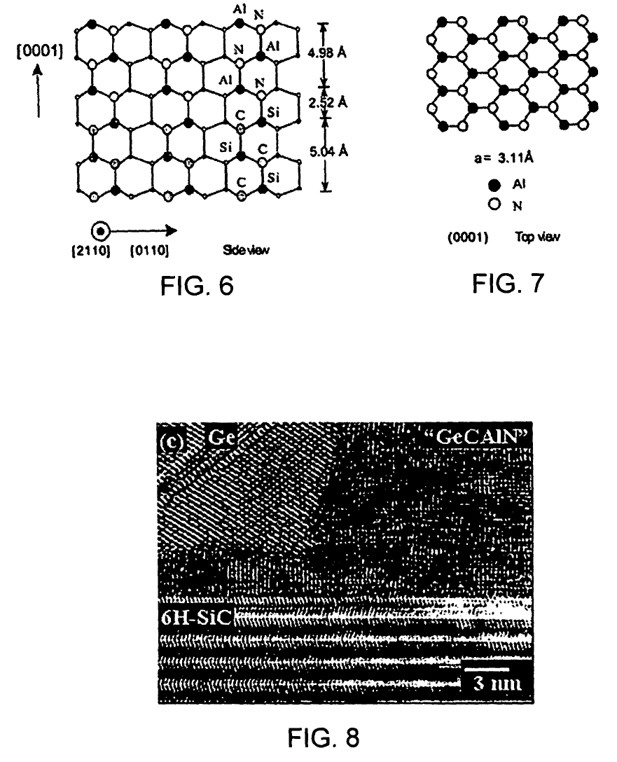

FIGS. 4 and 5 show a pair of XTEM images of a SiCAlN film grown on Si(111). FIG. 4 illustrates the columnar grains at higher magnification than FIG. 3. FIG. 5 illustrates the characteristic . . . ABAB . . . stacking. The 2H-wurtzite structure of the film is clearly visible in the high-resolution XTEM images of FIGS. 6 and 7, which illustrate a proposed model of the SiCAlN wurtzite structure. FIG. 6 is a side view of SiCAlN atomic structure and FIG. 7 is a top view of the same structure.

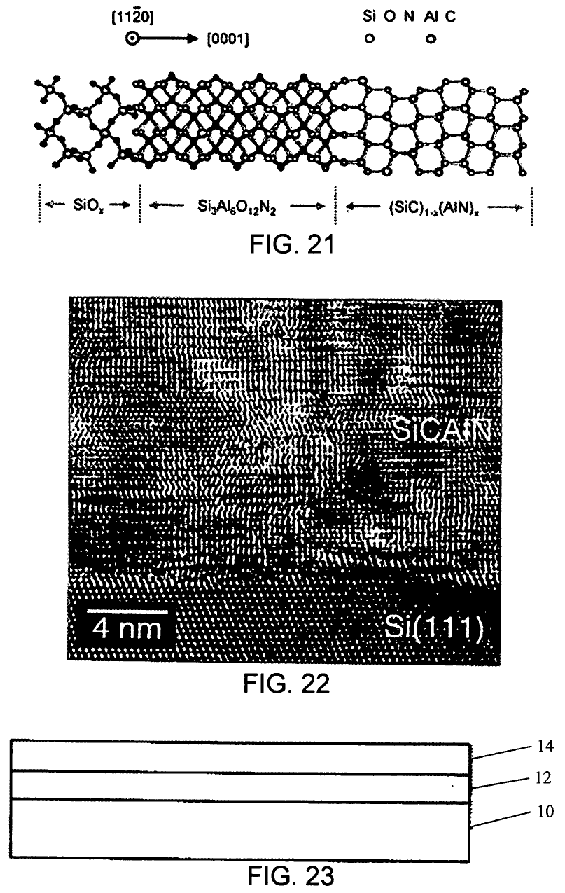

Growth of single-phase SiCAlN epitaxial films with the 2H-wurtzite structure is conducted directly on Si(Si111) despite the structural differences and large lattice mismatch (19%) between the two materials. Commensurate heteroepitaxy is facilitated by the conversion of native and thermally grown SiO₂ layers on Si(111) into crystalline oxides by in situ reactions of the layers with Al atoms and the H₃SiCN precursor, forming coherent interfaces with the Si substrate and the film. High-resolution transmission electron microscopy (TEM) illustrated in FIG. 22 and electron energy loss spectroscopy (EELS) illustrated in FIG. 20 show that the amorphous SiO₂ films are entirely transformed into a crystalline Si—Al—O—N framework in registry with the Si(111) surface. This crystalline interface acts as a template for nucleation and growth of epitaxial SiCAlN. Integration of wide bandgap semiconductors with Si is readily achieved by this process.

The SiCAlN film was deposited directly on the Si(111) substrate surface with its native oxide layer intact. The EELS spectra of the SiCAlN film obtained with a nanometer beam scanned across the interface show the presence of oxygen. XTEM images of the film/substrate interface show that the amorphous oxide layer has disappeared, replaced by a crystalline interface. It appears that deposition of the SiCAlN film results in the spontaneous replacement of the amorphous SiO₂ layer with a crystalline aluminum oxide layer which in turn promotes epitaxial growth of SiCAlN. FIG. 6 is an XTEM image of SiCAlN grown in Si(111) with a native SiO₂ coating showing the amorphous SiO₂ layer replaced with a crystalline aluminum oxide layer and the epitaxial SiCAlN grown thereon.

Characterization of the deposited films by a variety of spectroscopic and microscopic techniques yielded a near-stoichiometric composition throughout the columnar wurtzite structure with lattice parameters very close to those of 2H—SiC and hexagonal AlN. Transmission electron diffraction (TED) patterns revealed a disordered wurtzite material with lattice constants a=3.06Å and c=4.95Å, very close to those of 2H—SiC and hexagonal AlN. Analysis of the films with electron energy loss spectroscopy (EELS) with nanometer beam size showed the uniformity of elemental distribution throughout the SiCAlN film. The EELS results thus confirm that the film contains a solid solution of SiCAlN. All four constituent elements, Si, Al, C and N, appear together in every nanometer-scale region probed, without any indication of phase separation of SiC and AlN or any segregation of individual elements in the film. A model of the 2H hexagonal structure of SiCAlN is seen in the model in FIGS. 6 and 7.

Growth on the Si(111) with an intact native oxide layer, surprisingly, resulted in transparent crystalline SiCAlN films with significant epitaxial character. High-resolution cross-sectional electron microscopy (XTEM) images of the interface show that the amorphous native oxide was completely converted into a crystalline interface, which acts as a suitable template for nucleation and growth of SiCAlN. However, the limited thickness of the native oxide layer, i.e. ˜1 nm, made determination of the composition and structure of the interface difficult.

In experiments involving the native oxide, the as-received Si(111) wafer is used as substrate without prior chemical etching or any other surface preparation or treatment. The crystalline Si—Al—O—N layer can be obtained in situ during film growth at 750° C. by a side reaction between the native SiO₂ with the Al flux and N atoms furnished by the H₃SiCN precursor.

The best results are, however, obtained using a process that involves the deposition of two monolayers of Al on the SiO₂ surface followed by growth of a thin SiCAlN capping layer. Its purpose is to encapsulate the reaction zone thus isolating the Al/SiO₂ assembly to avoid loss of Al and SiO by evaporation during the course of the reaction. The system is annealed at 900° C. for 30 minutes. The bulk SiCAlN layer is then grown by reaction of Al and H₃SiCN at 750° C. The flux of each species was ˜6×10−13 cm−2 s−1 giving a Al/H₃SiCN flux ratio of 1:1. The base pressure of the MBE chamber was 2×10−10 Torr rising to 5×10−7 Torr during deposition. The growth rate of the SiCAlN was ˜4 nm per minute. Transparent films with nominal thickness of 150-300 nm were deposited under these conditions.

The morphology, microstructure and elemental concentration of the films were studied by XTEM and EELS. High resolution XTEM images illustrated in FIG. 22 showed heteroepitaxial growth of 2H—SiCAlN on a coherent and crystalline interface layer. This layer replaces the corresponding amorphous native SiO₂ and acts as compliant template, which presumably accommodates the enormous strain associated with the highly mismatched Si and SiCAlN structures. The EELS elemental profiles shown in FIG. 20 across the interface layer revealed predominately oxygen, aluminum and silicon as well as minor quantities of nitrogen, indicating the presence of a Si—Al—O—N layer grown directly adjacent to the Si substrate. The oxygen signal decreased rapidly across the thin (˜1 nm) interface to background levels in the SiCAlN film. The constituent elements in the SiCAlN layer appeared in every nanoscale region probed at concentrations close to stoichiometric values, consistent with the presence of a SiCAlN film grown on a thin oxynitride interface. The elemental content at the interface was difficult to determine quantitatively since the width of the interface layer, i.e. 1 nm, is comparable to the probe size. Nevertheless EELS provided useful qualitative information with regard to elemental content and showed that the interface layer did not segregate into Al₂O₃ and SiO₂. The near edge fine structure of the Si, Al and O ionization edges indicated a bonding arrangement consistent with a complex Si—Al—O—N phase.

Epitaxial SiCAlN Films Grown on Si(111) Having a Thermal Oxide Layer (˜4 nm)

SiCAlN film was grown on a Si(111) substrate with a 4-nm thick thermal oxide using the methods described herein. The SiCAlN epitaxial thin film was grown using these oxides as buffer layers and compliant templates. The composition and structure of these systems are based on the Si—Al—O—N family of silicon oxynitrides.

To determine the elemental concentrations quantitatively and to investigate the bonding properties of the interface layer, SiCAlN film was grown on Si (111) with a 4-nm thick thermally grown oxide as template. This 4-nm layer thickness is within the resolution of the EELS nanoprobe and is thus more suitable for precise analysis. A pre-oxidized Si(111) substrate with a 4-nm SiO₂ layer is heated at 700° C. in UHV to remove any hydrocarbon or other volatile impurities from the surface. The conversion of the amorphous SiO₂ to a crystalline Si—Al—O—N layer follows the procedure described for the native oxide preparation.

Rutherford backscattering spectrometry (RBS) was used to characterize the Si—C—Al—N composition of the films and to detect oxygen and other low level impurities. The 2 MeV spectra indicated that the Si and Al concentrations were 27 and 23 atomic % respectively. Resonant nuclear reactions at 4.27 and 3.72 MeV indicated that the C and N concentrations were 23-24 atomic % and 24-26 aomic % respectively. Oxygen depth profiles using a resonance reaction at 3.0 MeV did not show any oxygen impurities throughout the bulk SiCAlN layer. However, the data suggested the presence of a thin oxide layer at the Si interface. This indicates the presence of a two-layer heterostructure which consists of a thick SiCAlN film grown on a thin oxide interface. The FTIR spectra showed strong Si—C and Al—N peaks at 740 and 660 cm⁻¹, respectively, corresponding to the SiCAlN bulk film. The spectra also showed a weak peak at 1100 cm⁻¹ which is attributed to Si—O—Al type lattice modes consistent with the presence of the thin oxide layer in the film heterostructure.

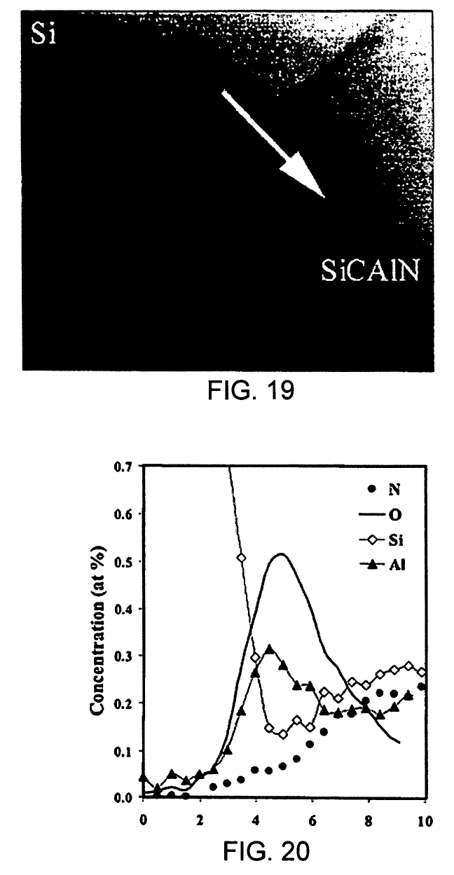

Electron microscopy in cross section (XTEM) was used to characterize the microstructure and morphology of the film. FIG. 19 is a typical annular dark-field image showing the SiCAlN film and the underlying oxide layer, visible as a band of darker contrast next to the Si interface. The band is coherent, continuous and fairly uniform with a thickness measured to be about 4 nm, a value close to that of the original SiO₂ layer. Spatially resolved (EELS) with a nanometer size probe was sued to examine the elemental concentration across the entire film thickness. The nanospectroscopy showed a homogeneous distribution of Si, C, Al and N throughout the SiCAlN layer, which is consistent with the formation of single-phase alloy material. Analysis across the dark band revealed significant concentrations of oxygen, aluminum and silicon at each nanometer step probed. A typical compositional profile derived from energy-loss line scans (FIG. 20) shows an enhancement of O and Al with a corresponding decrease in Si with respect to SiCAlN. A small concentration of N was also found, as shown in FIG. 20, indicating diffusion of N from the SiCAlN into the interface region presumably during the annealing step. The carbon content is effectively zero in this region indicating that the interface consists only of Si, Al, O and N. In order to determine quantitatively the composition of the interface region, it is necessary to convolve the effective electron probe distribution with model elemental distributions. This composition profile was modeled as simple step functions at the interface region. The best fit elemental step distributions and corresponding convolved profiles for Si, Al, O and N indicate the presence of a distinct aluminosilicate oxynitride layer with a graded composition yielding an average stoichiometry of Si_{0.14}Al_{0.28}O_{0.50}N_{0.08} over the 4.0 nm thickness. This composition is consistent with known X-silicon phases with stoichiometries ranging from Si₃Al₆O₁₂N₂ (Si_{0.13}Al_{10.26}O_{0.52}N_{0.09}) to the more silica-rich Si₁₂Al₁₈O₃₉N₈ (Si_{0.16}Al_{0.23}O_{0.51},N_{0.10}) [16]. X-silicon condenses in a triclinic structure which can be viewed as a distorted hexagonal lattice containing alternating chains of octahedra and tetrahedra linked to form sheets reminiscent of the mullite (Si₂Al₆O₁₃) structure as shown in FIG. 21. In the “low”-X phase of this “nitrogen”-mullite, the edge shared polyhedral sheets in the (100) plane are linked together by tetrahedral AlN₄ and SiO₄ units. A silica-rich “high”-X phase is similar, but possesses a faulted structure.

A typical high-resolution XTEM image of the siliconoxynitride interface heterostructure is shown in FIG. 22, revealing the epitaxial growth of a crystalline interface (buffer layer) which displays a microstructure indicative of a two-dimensional oxide system. There is a smooth transition between the Si (111) substrate, the interfacial layer and the SiCAlN overlayer. The SiCAlN is highly oriented and exhibits the expected 2H-wurtzite structure, as is clearly visible in the upper portion of the film. The microstructural and nanoanalytical data indicate that the thermal SiO₂ layer has been completely reacted to form a crystalline Si—Al—O—N interface serving as a suitable template for nucleation and growth of SiCAlN.

Growth of crystalline oxide layers directly on Si is a potentially important area of research that remains virtually unexplored. These crystalline oxides possess a wide range of novel properties uniquely suitable for a number of applications such as high-κ gate dielectrics. Development of epitaxial dielectrics on Si has been focused on simple silicates (Sr₂SiO₄) and perovskites (SrTiO₃) [17-19]. Silicates in the SiₓAl_{y}O_{z}, system have been previously investigated in reactions of Al with bulk SiO₂ between 550-850° C. [20, 21]. Although no structural and compositional data were provided, these systems were described as homogeneous ternary oxides that exhibit electronic properties similar to those of bulk glasses and zeolites. The inventors' work in this area is believed to represent the first example of a crystalline Si—Al—O—N material, which serves as a buffer layer between Si (111) and tetrahedral semiconductor alloys. These oxynitrides are, in general, high-compressibility (softer) solids compared to either SiCAlN or Si, thereby acting as a soft compliant spacer which can conform structurally and readily absorb the differential strain imposed by the more rigid SiCAlN and Si materials. This elastic behavior may be due to the structure and bonding arrangement consisting of sheet-like edge-shared octahedra and corner-shared tetrahedra which provide a low-energy deformation mechanism involving bond bending forces rather than bond compression forces.

The results of the inventors' work in this area suggest that a complex oxide material is the crucial interface component that promotes epitaxial growth of SiCAlN heterostructures on Si (111). This crystalline oxide is formed by in situ reactions using native and thermal SiO₂ as templates at the Si interface. Integration of wide bandgap nitride semiconductors with Si is readily achieved with the SiCAlN/Si—Al—O—N/Si(111) system serving as an ideal buffer layer. The structural model of FIG. 21 illustrates the transition of the interface structure from silica to SiCAlN through an intermediate Si₃Al₆O₁₂N₂ framework of a sheet-like structure.

Epitaxial XCZN films grown on Si(0001)

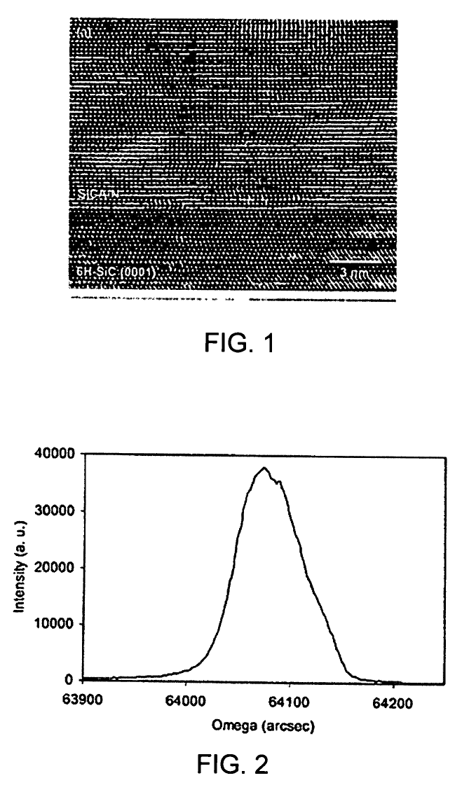

Deposition on α-SiC(0001) substrates is virtually homoepitaxy which leads to a low density of misfit and threading dislocations desirable in semiconductors. In those instances wherein silicon is the substrate, a native SiO₂ layer is generally present, and the quaternary film is deposited on the SiO₂ layer. It has been observed that in the present method, the amorphous oxide layer is largely replaced with a crystalline aluminum oxide layer which in turn promotes epitaxial growth of the quaternary film. FIG. 1 illustrates this phenomenon. FIG. 1 is a high-resolution the cross-sectional transmission electron microscopy (XTEM) image of an epitaxial SiCAlN film grown on α-Si(0001) by the method of the present invention. FIG. 2 is an X-ray rocking curve of an on-axis SiCAlN(0002) peak of the SiCAlN film illustrated in FIG. 1.

Epitaxial XCZN Films Grown on Group III Nitride Buffer Layer

In other preferred embodiments of the invention, quaternary epitaxial films were grown on a buffer layer on the silicon substrate. In contrast to growth of SiCAlN on α-SiC(0001) substrates, there may be a large lattice mismatch between the SiCAlN film and the Si(111) substrate. In order to improve epitaxial growth of SiCAlN on Si(111), a buffer layer on Si(111) may be deposited on the Si(111) substrate prior to growth of SiCAlN. The preferred buffer layer is aluminum nitride (AlN). An AlN buffer layer may be deposited by methods known in the art, as, for example, the method disclosed in U.S. Pat. No. 6,306,675 issued to I. S. T. Tsong, et al., for “Method for forming a low-defect epitaxial layer in the fabrication of semiconductor devices,” herein incorporated by reference. Generally, the AlN buffer layer may be deposited through a precursor containing the AlN species or in other instances Al may be provided by evaporation from an effusion cell and combined with N-atoms from a radio-frequency plasma source. Both types of deposition take place in a conventional MBE chamber.

In certain instances, the epitaxial film is deposited on a buffer layer on the silicon substrate. In these instances, the buffer layer provides improved lattice matching for epitaxial growth of the film. Deposition on AlN/Si(111) substrates, for example, is virtually homoepitaxy which leads to a low density of misfit and threading dislocations desirable in semiconductors useful in a variety of optoelectronic and microelectronic applications. Preferred buffer layers are the Group III nitrides, aluminum nitride (AlN), germanium nitride (GeN), indium nitride (InN), aluminum gallium nitride (AlGaN) and indium gallium nitride (InGaN), most preferably AlN.

Layered semiconductor structures comprising a buffer layer and a quaternary epitaxial film having the formula XCZN deposited on the layer are provided. FIG. 18 illustrates a model of a layered semiconductor structure 1 comprising semiconductor quaternary film XCZN 6, buffer layer 4 and substrate silicon or silicon carbide 2.

GeCAlN Thin Films

A method for preparing epitaxial quaternary films of the formula GeCZN wherein Z is a Group III element will now be described. Epitaxial quaternary films of the formula GeCZN wherein Z is aluminum, gallium or indium or, in certain instances, transition metals, are also wide bandgap semiconductors and are an alternative optoelectronic material to SiCAlN because of the theoretical bandgap of 1.6 eV for GeC [14].

Quaternary GeCAlN compounds are prepared by the present method by providing the precursor D₃GeCN. A flux of gaseous precursor, unimolecular D₃GeCN molecules, and vapor flux of Al atoms are introduced into the GSMBE chamber maintained at a pressure whereby the precursor and Al atoms combine to form epitaxial GeCAIN thin film the substrate. Temperature during the reaction is less than 1000° C., most preferably between about 550° C. to 750° C. Substrate is silicon, preferably Si (111) or α-SiC(0001). In certain other instances, a transition metal, Ti, or Zr, e.g., may be supplied from an effusion cell to form a series of quaternary compounds of different metal atoms.

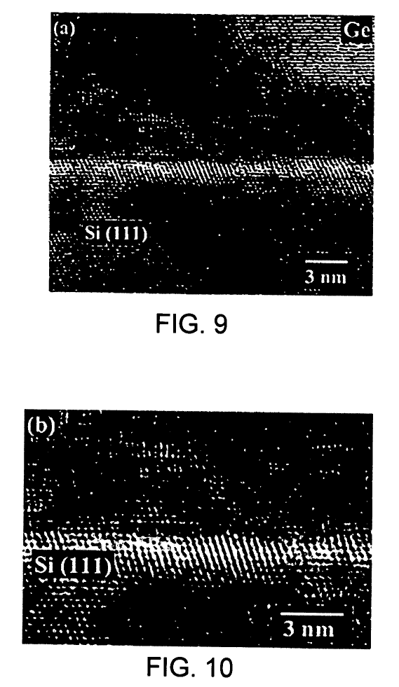

The microstructures of GeCAIN films deposited at 650° C. on Si and SiC substrates are shown in XTEM images in FIGS. 8, 9 and 10. FIG. 8 is an XTEM image of GeCAIN film grown on 6H—SiC(0001) substrate showing epitaxial interface and Ge precipitate. FIG. 9 shows a crystalline film with Ge precipitate, and FIG. 10 shows the transition from cubic Si(111) to hexagonal structure of the film at the interface. The diffraction data indicate that this material consists of cubic Ge particles and disordered hexagonal crystals containing all the constituent elements, Ge, Al, C and N, according to EELS analyses. RBS analyses revealed that while the Al, C and N contents are nearly equal, the Ge concentration is substantially higher than the ideal 25% value. Similar to the growth of SiCAlN on Si(111) substrates with intact native oxide layers, the XTEM images of GeCAlN/Si interfaces are as depicted in FIGS. 9 and 10. This shows a clear transition from cubic structure of the substrate to hexagonal structure of the film without the amorphous oxide layer.

Analysis and Characterization of Epitaxial Quaternary Films Grown by the Method of the Present Invention.

A detailed characterization of the present quaternary XCZN films was provided by a thorough analysis utilizing a variety of techniques. The films may be more thoroughly understood in accordance with the figures and with the results given in the following subsections entitled: (1) Composition determined by Rutherford backscattering analysis; (2) Fourier transform infrared spectroscopy (FTIR); (3) Cross-sectional transmission electron microscopy (XTEM); (4) Transmission electron diffraction (TED); (5) Energy loss spectroscopy (EELS); (6) Bandgap measurements; (7) Surface Morphology; and (8) Hardness measurements.

(1) Composition of SiCAlN Films Determined by Rutherford Backscattering (RBS)

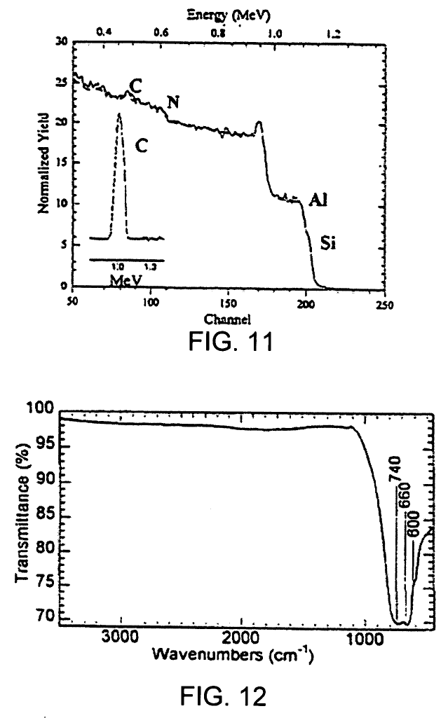

Rutherford backscattering spectrometry (RBS) was used to determine the elemental composition, detect H and O impurities, and estimate the film thickness. The Si and Al elemental concentrations of each film were measured at 2 MeV, and resonant nuclear reactions at 4.27 MeV and 3.72 MeV were used to determine the C and N contents respectively. Results of this analysis are illustrated in FIG. 11.

The C and N concentrations in most films were nearly equal, at 23-24 at. % and 24-26 at. % respectively, suggesting that the entire C—N unit of the precursor was incorporated into the film. The Al concentration in all films was 21-23 at. %, consistent with the high affinity of Al for the N ligand, but always slightly lower than that of C and N. The Si content for all films was measured at 27-29 at. %, consistently higher than the ideal 25 at. %. Typical compositions of the SiCAlN films determined by RBS lie in the following range: Si 27-29 atomic %, Al 21-23 atomic %, C 23-24 atomic %, and N 24-26 atomic %. The Si content is consistently higher than the stoichiometric 25 atomic %. This anomaly can be attributed to a minor loss of C—N during deposition of the precursor. Alternatively, the replacement of weaker Al—C bonding (which is present in an ideally stoichiometric SiCAlN solid solution) by stronger Si—C bonding at some lattice sites may account for the excess Si over Al. Oxygen resonance at 3.05 MeV confirmed the absence of any measurable O impurities in the bulk. Forward recoil experiments showed only background traces of H, indicating the complete elimination of H ligands from the precursor during growth. Depth profiling by secondary ion mass spectrometry (SIMS) showed homogeneous elemental distribution throughout and confirmed the absence of O and other impurities.

(2) Fourier Transform Infrared Spectroscopy of SiCAlN Films (FTIR)

Fourier transform infrared spectroscopy (FTIR) in the transmission mode was used to examine the bonding properties of the constituent elements in all films. Results are illustrated in FIG. 12. The FTIR spectrum shows two broad peaks at wavenumbers 740 cm⁻¹ and 660 cm⁻¹ corresponding to Si—C and Al—N lattice vibrations respectively. These wavenumbers are significantly lower than those of pure Si—C (800 cm⁻¹) and pure Al—N (690 cm⁻¹), consistent with the formation of an extended alloy between the two binary systems. A lower intensity peak is also observed at 600 cm⁻1 and is assigned to Al—C type lattice vibrations. Bands between 800-900 cm⁻¹ are assigned to Al—C type lattice vibrations. Bands between 800-900 cm⁻¹ which would correspond to Si—N stretching absorptions are not clearly resolved in the spectrum in FIG. 12. However, their presence cannot be ruled out because it is likely that they overlap with the broad onset of the Si—C absorption. The spectrum in FIG. 12 does not show any additional peaks attributable to Si—H vibrations between 2200-2100 cm⁻¹, confirming the elimination of the H ligand from the precursor.

Absorption spectra taken from Fourier transform infrared spectroscopy (FTIR) show major peaks due to Si—C and Al—N lattice vibrations and minor peaks due to Al—C and Si—N vibrations, in agreement with the wurtzite structure and chemical bonding of the SiCAlN film.

(3) Cross-Sectional Transmission Electron Microscopy

The microstructure of the films was studied by cross-sectional transmission electron microscopy (XTEM). A typical high-resolution XTEM image of the epitaxial growth of SiCAlN on an α-SiC(0001) substrate is shown in FIG. 1. The characteristic . . . ABAB . . . stacking of the 2H wurtzite structure is clearly visible in the grains of the film shown in FIG. 1. A model atomic structure proposed for the SiCAlN epitaxial film is shown in FIGS. 6 and 7. A typical XTEM image of a SiCAlN film grown on a Si(111) substrate is shown in FIGS. 3 and 4 revealing columnar grains ˜25 nm wide extending from the film/substrate interface through the entire layer. The XTEM images of the SiCAlN film grown on Si(111) include some columnar grains with a-lattice planes oriented normal instead of parallel to the interface (FIG. 3).

(4) Transmission Electron Diffraction

Transmission electron diffraction (TED) patterns of SiCAlN films give lattice constants of a=3.06Å and c=4.95Å, very close to those of 2H—SiC and hexagonal AlN. Transmission electron diffraction (TED) patterns indicate a disordered wurtzite material with lattice constants a=3.06 Å and c=4.95 Å, very close to those of 2H—SiC and hexagonal AlN. A survey of digital diffractograms of the lattice fringes indicates that the lattice spacings are constant throughout the grains, and close to the values obtained from TED patterns.

(5) Energy Loss Spectroscopy of SiCAlN Films

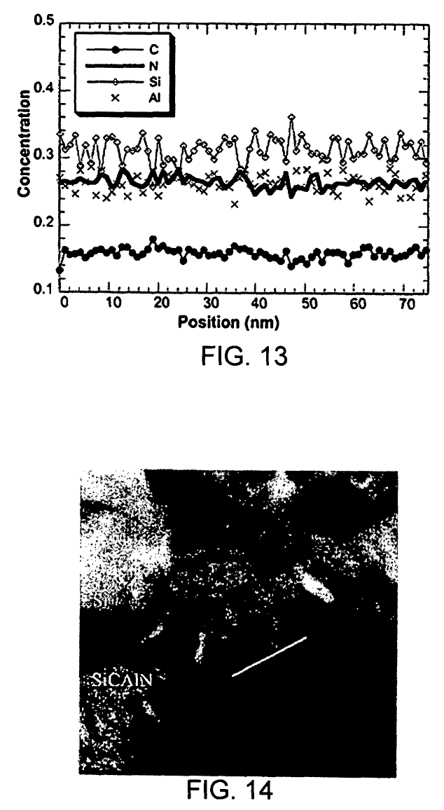

Electron energy loss spectroscopy (EELS) with nanometer beam size was used to study the uniformity of elemental distribution throughout the film. Typical elemental profiles scanned across the columnar grains in the film are shown in FIG. 13 which is an EELS elemental profile scan of Si, Al, C and N sampled across 70 nm over a SiCAlN film showing the distribution of all four constituent elements. The corresponding RBS atomic concentrations for Si, Al, N, and C are 29, 21, 26, and 24 at. % respectively. The lower C content detected by EELS is due to preferential depletion of C from the lattice sites by the electron beam. The region where the scan took place on the film is shown as a white line in the XTEM image of FIG. 14.

All four constituent elements, Si, Al, C and N, appear together in every nanometer-scale region probed, without any indication of phase separation of SiC and AlN or any segregation of individual elements in the film.

The EELS results are accurate to within 10 at. % and thus confirm that the film contains a solid solution of SiCAlN. The minor elemental variations observed in FIG. 13 may be due to compositional inhomogeniety across grain boundaries. While the EELS elemental concentrations for N, Al, and Si in all samples are close to those obtained by RBS (certainly within the 10% error associated with the technique) the EELS elemental concentration of C is consistently lower by a significant amount than the RBS value. This is due to the preferential depletion of C from the lattice sites by the finely focused intense electron beam.

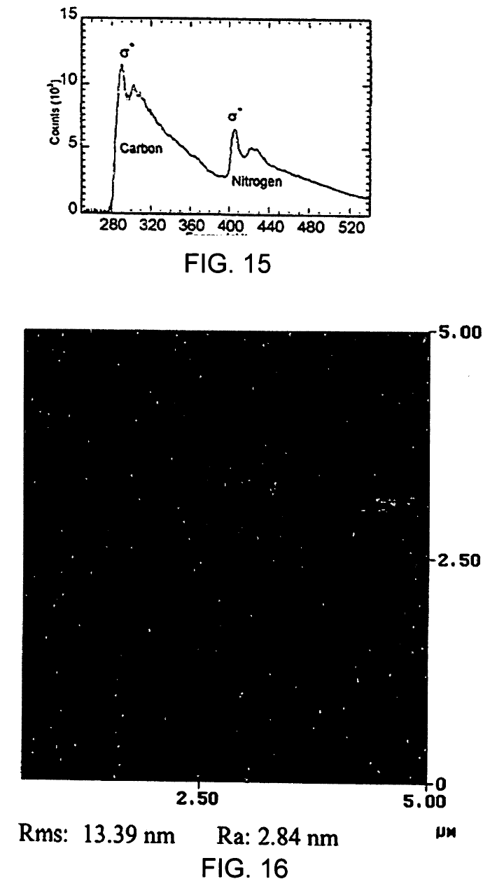

An EELS spectrum featuring K-shell ionization edges representing the σ* transition for both C and N is shown in FIG. 15. Peaks corresponding to π* transitions characteristic of sp² hybridization are not observed at these edges, indicating the absence of sp² hybridization are not observed at these edges, indicating the absence of sp² hybridized carbon and related planar C—N networks generally associated with the decomposition of the unimolecular precursor. The EELS spectrum thus confirms that both C and N are sp³ hybridized and tetrahedrally coordinated as in SiC and AlN.

(6) Bandgap Measurements

Optical absorption experiments suggest that the bandgap for the SiCAlN epitaxial film is no less than 3.8 eV, as would be expected from the bandgaps of the constituents SiC (3.3 eV) and AlN (6.3 eV). The direct bandgap of the SiCAlN films may be observed by vacuum ultraviolet (VUV) ellipsometry.

(7) Surface Morphology

Atomic force microscope images illustrated in FIGS. 16 and 17 show a relatively smooth as-grown surface of a SiCAlN thin film grown according to the method of the present invention. The complete lack of facets on the as-grown surface indicates that the predominant growth direction is basal-plane, i.e. (0001), oriented.

(8) Hardness Measurements

The SiCAlN solid solution films can also serve as superhard coatings for protection of surfaces against wear and erosion. The hardness of the films was measured using a Hysitron Triboscope attached to a Digital Instruments Nanoscope III atomic force microscope. The hardness in this case is defined as the applied load divided by the surface area of the impression when a pyramidal-shaped diamond indentor is pressed normally into the film surface. Using the hardness value of 9 GPa measured for fused silica as a standard, the indentation experiments yielded an average hardness of 25 GPa for the SiCAlN films, close to that measured for sapphire under the same experimental conditions. The reported Vickers hardness for SiC and AlN are 28±3 and 12±1 Gpa, respectively [1].

Integration of wide Bandgap Nitride Semiconductors with Si

In accordance with the present invention, wide bandgap nitride semiconductors can be integrated with Si to form semiconductor structures and active electronic devices. The above-described method can be used to grow high purity, low defect, device-quality SiCAlN epitaxial films on silicon and silicon carbide substrates at temperatures in the range of 550-750° C. by means of gas source molecular beam epitaxy (GSMBE). The SiCAlN epitaxial film can be grown on a Si(111) substrate with a Si—Al—O—N interface layer. With these systems, integration of wide bandgap nitride semiconductors with Si can be readily achieved and active electronic devices can be fabricated for a variety of optoelectronic and microelectronic applications.

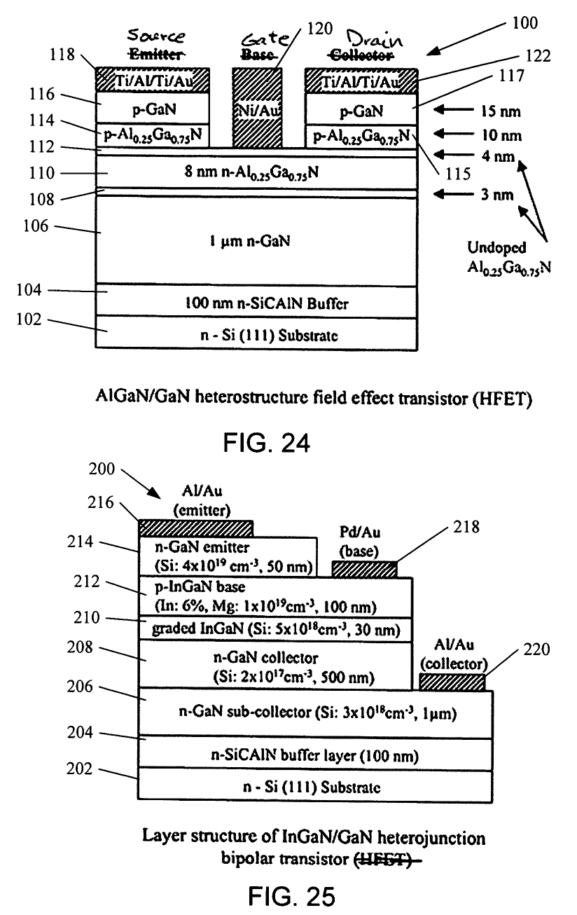

FIGS. 24-28, which will now be discussed in more detail, show illustrative examples of such devices.

### EXAMPLE 1

### Field Effect Transistors

FIG. 24 shows an example of an AlGaN/GaN heterostructure field effect transistor (HFET) 100 in accordance with the present invention. As shown in FIG. 24, the structure includes a Si(111) substrate 102 with a 100 nm thick n-type SiCAlN buffer layer 104 grown on the substrate 102 using the process described above for growing epitaxial thin film SiCAlN on silicon. The following layers are then formed over the buffer layer 104: an n-type GaN layer 106; an undoped Al_{0.25}GA_{0.75}N spacer layer 108; an n-type Al_{0.25}GA_{0.75}N barrier layer 110; an undoped Al_{0.25}GA_{0.75}N contact layer 112; a p-type Al_{0.25}GA_{0.75}N cap layers 114, 115; and p-type GaN cap layers 116, 117. Ohmic contacts 118, 122 are formed on the surface of each of the cap layers 116, 117, respectively, using Ti/Al/Ti/Au metal to form source and gate contacts. An ohmic contact 120 is formed on the surface of the undoped layer 112 using Ni/Au metal to form a gate contact.

N. Maeda, T. Saitoh, K. Tusubaki and N. Kobayashi, in their article entitled “AlGaN/GaN Heterostructure Field-Effect Transistors with High Al Compositions Fabricated with Selective-Area Regrowth,” Phys. Stat. Sol. (a) 188, No. 1, pp. 223-226 (2001) [23], which is incorporated herein by this reference, describe in further detail a process for fabricating the layers 106, 108, 110, 112, 114, 115, 116 and 117 and the ohmic contacts 118, 120, 122 to form the HFET 100. The structure is grown by metal organic vapor phase epitaxy (MOVPE). The n-type GaN layer 106 has a thickness of 1 μm. The spacer layer 108 has a thickness of 3 nm. The barrier layer 110 has a thickness of 8 nm. The contact layer 112 has a thickness of 4 nm. The Al_{0.25}GA_{0.75}N cap layers 114, 115 have a thickness of 10 nm. The GaN cap layers 116, 117 have a thickness of 15 nm.

Another example of a microelectronic device that can be grown by metal organic chemical vapor deposition (MOCVD) on a Si(111) substrate with a SiCAlN buffer layer according to the present invention is the GaN high electron mobility transistor (HMET). One skilled in the art can fabricate such HMETs using processes that previously have been used to grow HMET structures on SiC substrates and sapphire substrates using MOCVD. For example, N.-Q. Zhang, B. Moran, S. P. DenBaars, U. K. Mishra, X. W. Wang and T. P. Ma, in the article entitled “Kilovolt AlGaN/GaN HEMTs as Switching Devices,” Phys. Stat. Sol. (a) 188, No. 1, pp. 213-217 (2001) [24], which article is incorporated herein by reference, describe the structure and fabrication of GaN high electron mobility transistors (HMETs) grown on SiC substrates by MOCVD. Also, M. Akita, K. Kishimoto and T. Mizutani, in the article entitled “Temperature Dependence of High-Frequency Performances of AlGaN/GaN HEMTs,” Phys. Stat. Sol. (a) 188, No. 1, pp. 207-211 (2001) [25], which article also is incorporated herein by reference, describe the structure and fabrication of AlGaN/GaN HMETs grown on shaphire substrates by MOCVD.

### EXAMPLE 2

### Double Heterojunction Bipolar Transistor

FIG. 25 shows an example of an Npn InGaN/GaN double heterojunction bipolar transistor (DHBT) 200 having a SiCAlN buffer layer 204 formed on a Si(111) substrate 202, in accordance with the present invention. As shown in FIG. 25, the structure includes an n-type Si(111) substrate 202 with a 100 nm n-type SiCAlN buffer layer 204 deposited on the substrate 202 using the process described above for growing epitaxial thin film SiCAlN on silicon. The following layers can be grown over the buffer layer 204 by low-pressure metalorganic vapor phase epitaxy and can be defined by electron cyclotron resonance plasma etching: an n-type GaN sub-collector layer 206; an n-type GaN collector layer 208; a graded InGaN layer 210; a p-type InGaN base layer 212; and an n-type GaN emitter layer 214. An n-type ohmic contact 216 is formed on the surface of the n-type emitter layer 214 using Al/Au metal. A p-type ohmic contact 218 is formed on the surface of the p-type emitter layer 218 using Pd/Au metal. An n-type ohmic contact 220 is formed on the surface of the n-type sub-collector layer 206 using Al/Au metal.

T. Makimoto, K. Kumakura and N. Kobayashi, in “High Current Gains Obtained by InGaN/GaN Double Heterojunction Bipolar Transistors ”, Phys. Stat. Sol. (a) 188, No. 1, pp. 183-186 (2001) [26], which article is incorporated herein by this reference, describe in further detail the structure and fabrication of the layers 206, 208, 210, 212 and 214 to form an InGaN/GaN double heterojunction bipolar transistor. The n-GaN sub-collector layer 206 has a thickness of 1 μm and a Si doping concentration of 3×10¹⁸ cm⁻³. The n-GaN collector layer 208 has a thickness of 500 nm and a Si doping concentration of 5×10¹⁸ cm⁻³. The graded InGaN layer 210 has a thickness of 30 nm and a Si doping concentration of 2×10¹⁷ cm⁻³. The p-InGaN base layer 212 has a thickness of 100 nm and an In mole fraction of 0.06. The Mg doping concentration in the base layer 212 is 1×10¹⁹ cm⁻³, corresponding to a hole concentration of 5×10¹⁸ cm⁻³ at room temperature. The n-GaN emitter layer 214 has a thickness of 50 mm and a Si doping concentration of 4×10¹⁹ cm⁻³.

### EXAMPLE 3

### Laser Diodes

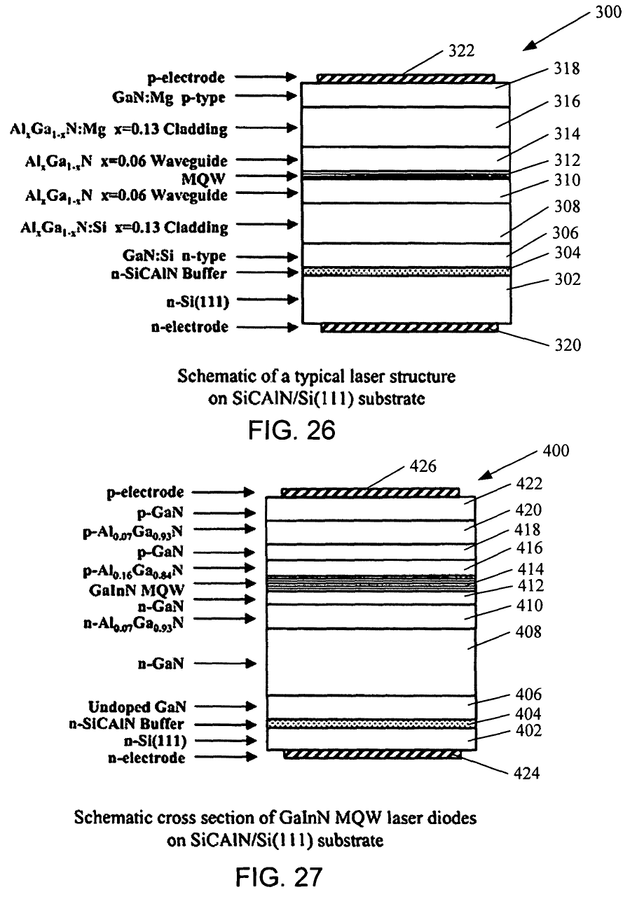

FIG. 26 shows an example of a typical laser structure 300 having a SiCAlN buffer layer 304 formed on a Si(111) substrate 302 in accordance with the present invention. As shown in FIG. 26, the structure 300 has an n-type Si(111) substrate 302 with an n-type SiCAlN buffer layer 304 deposited on the substrate 302. The buffer layer 304 can be grown on the substrate 302 using the process described above for growing epitaxial thin film SiCAlN on silicon. The following layers are formed over the buffer layer 304: a Si-doped n-type GaN layer 306; a Si-doped Al_{0.13}Ga_{0.87}N cladding layer 308; an Al_{0.06}Ga_{0.94}N waveguide layer 310; a multi-layer quantum well active layer 312; an Al_{0.06}Ga_{0.94}N waveguide layer 314; a Mg-doped Al_{0.13}Ga_{0.87}N cladding layer 316; and a Mg-doped p-type GaN contact layer 318. An n-type electrode 320 is formed on the rear surface of the substrate 302, and a p-type electrode 322 is formed on a surface of the contact layer 318.

FIG. 27 shows another example of a semiconductor structure for a GaInN MQW laser diode 400 having a SiCAlN buffer layer 404 formed on a Si(111) substrate 402 in accordance with the present invention. As shown in FIG. 27, the structure has an n-type Si(111) substrate 402 with an n-type SiCAlN buffer layer 404 deposited on the substrate 402 using the process described above. The following layers are formed over the buffer layer 404: an undoped GaN layer 406; an n-type GaN layer 408; an n-type Al_{0.07}Ga_{0.93}N lower cladding layer 410; an n-type GaN waveguide layer 412; an undoped GaInN MQW active layer 414; a p-type Al_{0.16}Ga_{0.84}N capping layer 416; a p-type GaN waveguide layer 418; a p-type Al_{0.07}Ga_{0.93}N upper cladding layer 420; and a p-type GaN contact layer 422. An n-type electrode 424 is formed on the rear surface of the n-type Si(111) substrate 402, and a p-type electrode 426 is formed on a surface of the p-type contact layer 422.

F. Nakamura, T. Kobayashi, T. Asatsuma, K. Funato, K. Yanashima, S. Hashimoto, K. Naganuma, S. Tomioka, T. Miyajima, E. Morita, H. Kawai and M. Ikeda, in their article entitled “Room-temperature pulsed operation of a GaInN multiple-quantum-well laser diode with optimized well number,” Journal of Crystal Growth 189/190, pp. 841-845 (1998) [27], which is incorporated herein by this reference, describe details of the structure and fabrication of a GaInN multiple quantum well (MQW) laser diode having such layers deposited on a buffer layer. A. Kuramata, K. Domen R. Soejima, K. Horino, S. Kubota and T. Tanahashi, in an article entitled “InGaN laser diode grown on 6H—SiC substrate using low pressure metalorganic vapor phase epitaxy,” Journal of Crystal Growth 189/190 pp. 826-830 (1998) [28], which is incorporated herein by this reference, also describe details of the structure and fabrication of a GaInN MQW laser diode having such layers deposited on a buffer layer 404.

Also, J. Han, K. E. Waldrip, J. J. Figiel, S. R. Lee and A. J. Fischer, in their article entitled “Optically-pumped UV Lasing from a GaN-based VCSEL,” [29], which is incorporated herein by this reference, describe the structure and fabrication of a vertical-cavity surface-emitting laser (VCSEL) structure with GaN/AlGaN distributed Bragg reflectors (DBRs). Using the techniques described by Han, et al., VCSELs with GaN/AlGaN DBRs can be grown on a SiCAlN buffer layer formed on a Si(111) substrate according to the process described above.

### EXAMPLE 4

### LEDs

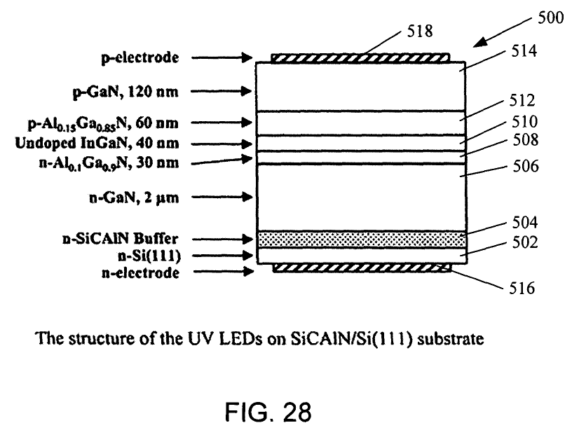

FIG. 28 shows an example of a UV LED structure 500 having a SiCAlN buffer layer 504 formed on a Si(111) substrate 502 in accordance with the present invention. As shown in FIG. 28, the structure has an n-type Si(111) substrate 502 with an n-type SiCAlN buffer layer 504 deposited on the substrate 502, which can be grown according to the processes described above. The following layers are formed over the buffer layer 504: a 2 μm thick n-type GaN layer 506; a 30 nm thick n-type Al_{0.16}Ga_{0.9}N cladding layer 508; a 40 nm thick undoped InGaN active layer 510; a 60 nm thick p-type Al_{0.15}Ga_{0.85}N cladding layer 512; a 120 nm thick p-type GaN layer 514. An n-type electrode 516 is formed on an exposed surface of the n-type Si(111) substrate 502, and a p-type electrode 518 is formed on a surface of the p-type GaN layer 514.

T. Mukai, D. Morita and S. Nakamura, in the article entitled “High-power UV InGaN/AlGaN double-heterostructure LEDs,” Journal of Crystal Growth 189/190 pp.778-781 (1998) [30], which is incorporated herein by this reference, describe details of the structure and fabrication of the layers of a InGaN/AlGaN light emitting diodes which can be deposited on a SiCAlN buffer layer.

### OTHER EXAMPLES

In addition to the substrate materials discussed above, the substrate material of a semiconductor structure in accordance with the invention may comprise silicon germanium (SiGe). Other potentially suitable compounds for the active region of the semiconductor structure may include, for example: BaTiO₃, KNbO₃, KnbTaO₃, the use of which is known for waveguides and optical amplifiers; La(x)Sr(1−x)CoO₃, LaSrTiO₃, the use of which is known for ferroelectrics for capacitors and for transducers; and BaSrTiO₃, HfO₂, ZrO₂, and Al₂O₃, the use of which is known for high K dielectrics.

### CONCLUSION

The above-described invention possesses numerous advantages as described herein. The invention in its broader aspects is not limited to the specific details, representative devices, and illustrative examples shown and described. Those skilled in the art will appreciate that numerous changes and modifications may be made to the preferred embodiments of the invention and that such changes and modifications may be made without departing from the spirit of the invention. It is therefore intended that the appended claims cover all such equivalent variations as fall within the true spirit and scope of the invention.

### REFERENCES

The following references are incorporated herein in their entirety:

1. Teter, D M, MRS Bulletin 23(1), 22 (1998).

2. Moroc, H, Strite, S, Gao, G B Lin, M E, Sverdlov B., Burns, M, J Appl. Phys. 76, 1363 (1994).

3. Tanaka, S, Kern R S, Davis R, Appl. Phys. Lett. 66, 37 (1995).

4. Ruh R, Zangvil, A, J. Am. Ceram. Soc. 65, 260 (1982).

5. Rafaniello, W, Plichta, M R, Virkar, A V, J. Am. Ceram. Soc 66, 272 (1983).

6. Zangvil, A, Ruh, R, J. Am. Ceram. Soc 71, 884 (1988).

7. Parker E. H. C(Ed.), “The Technology and Physics of Molecular Beam Epitaxy” Plenum Press (1985).

8. Kern, R S, Rowland, L B, Tanaka, S, Davis, R F, J. Mater. Res. 8, 1477 (1993).

9. Kern, R S, Rowland, L B, Tanaka, S, Davis, R F, J. Mater. Res. 13, 1816 (1998).

10. Jenkins, I, Irvine, K G, Spencer, M G, Dmitriev, V, Chen, N J, Cryst. Growth 128, 375 (1993).

11. Safaraliev, G K, Tairov, Yu M, Tsvetkov, V,F, Sov. Phys. Semicond. 25, 865 (1991).

12. McDiarmid, A G, Inorganic and Nuclear Chemistry, 1956, 2, 88-94. 13. Goldfarb, T D, The Journal of Chemical Physics 1962, 37, (642-646.).

14. Pandey, R, Rerat, M, Darrigan, C, Causa, M, J. Appl. Phys. 88, 6462 (2000).

15. Roucka, R, Tolle, J, Chizmeshya, A V G, Crozier, P A, Powelieit, C D, Smith, D J, Tsong, I S T and Kouvetakis, J Phys. Rev. Lett. (in press).

16. Schmucker, M and Schneider, H, J. Am. Ceeram. Soc. 82, 1934 (1999).

17. Liang, Y, Gan, S and Engelhard, M, Appl. Phys. Lett. 79, 3591 (2001).

18. McKee, R A, Walker, F J and Chisholm, M F, Phys. Rev. Lett. 81, 3014 (1998).

19. Yu, S, Ramdani, J, Finder, J M, Overgard, C D, Corner, J R and Kaushik, V S, J. Vac. Sci. Technol. B18, 1653 (2000).

20. Anandan, C, Appl. Surf. Sci. 89, 57 (1995).

21. Grundling, C, Lercher, J A and Goodman, D W, Surf. Sci. 318, 97 (1994).

22. Roucka, R, Tolle, J, Smith, D J, Crozier, P, Tsong, I S T and Kouvetakis, J, Appl. Phys. Lett. 79, 2880 (2001).

23. N. Maeda, T. Saitoh, K. Tusubaki and N. Kobayashi, “AlGaN/GaN Heterostructure Field-Effect Transistors with High Al Compositions Fabricated with Selective-Area Regrowth,” Phys. Stat. Sol. (a) 188, No. 1, pp. 223-226 (2001).

24. N.-Q. Zhang, B. Moran, S. P. DenBaars, U. K. Mishra, X. W. Wang and T. P. Ma, “Kilovolt AlGaN/GaN HEMTs as Switching Devices,” Phys. Stat. Sol. (a) 188, No. 1, pp. 213-217 (2001).

25. M. Akita, K. Kishimoto and T. Mizutani, “Temperature Dependence of High-Frequency Performances of AlGaN/GaN HEMTs,” Phys. Stat. Sol. (a) 188, No. 1, pp. 207-211 (2001).

26. T. Makimoto, K. Kumakura and N. Kobayashi, “High Current Gains Obtained by InGaN/GaN Double Heterojunction Bipolar Transistors ”, Phys. Stat. Sol. (a) 188, No. 1, pp. 183-186 (2001).

27. F. Nakamura, T. Kobayashi, T. Asatsuma, K. Funato, K. Yanashima, S. Hashimoto, K. Naganuma, S. Tomioka, T. Miyajima, E. Morita, H. Kawai and M. Ikeda, “Room-temperature pulsed operation of a GaInN multiple-quantum-well laser diode with optimized well number,” Journal of Crystal Growth 189/190, pp. 841-845 (1998).

28. A. Kuramata, K. Domen R. Soejima, K. Horino, S. Kubota and T. Tanahashi, “InGaN laser diode grown on 6H—SiC substrate using low pressure metalorganic vapor phase epitaxy,” Journal of Crystal Growth 189/190, pp. 826-830 (1998).

29. J. Han, K E. Waldrip, J. J. Figiel, S. R. Lee and A. J. Fischer, “Optically-pumped UV Lasing from a GaN-based VCSEL,”

30. T. Mukai, D. Morita and S. Nakamura, “High-power UV InGaN/AlGaN double-heterostructure LEDs,” Journal of Crystal Growth 189/190 pp.778-781 (1998).

What is claimed is:

1. A semiconductor structure comprising: a substrate; a SiCAlN region formed over the substrate, and an active region formed over the SiCAlN region.

2. The semiconductor structure of claim 1 wherein the active region comprises a gallium nitride region.

3. The semiconductor structure of claim 2, wherein the active region comprises a compound of the group consisting of GaN, AlGaN, InGaN, AlInGaN, AlN and InN.

4. The semiconductor structure of claim 1, further comprising a crystalline oxide interface formed between the substrate and the SiCAlN region.

5. The semiconductor structure of claim 4 wherein the crystalline oxide interface comprises Si—Al—O—N.

6. The semiconductor structure of claim 1, wherein the substrate comprises a silicon substrate.

7. The semiconductor structure of claim 1, wherein the substrate comprises a silicon carbide substrate.

8. The semiconductor structure of claim 1, wherein the substrate comprises a silicon germanium substrate.

9. The semiconductor structure of claim 1, wherein the active region comprises a compound of the group consisting of BaTiO₃, KNbO₃ and KnbTaO₃.

10. The semiconductor structure of claim 1, wherein the active region comprises a compound of the group consisting of La₍ₓ₎Sr₍₁₋ₓ₎CoO₃ and LaSrTiO₃.

11. The semiconductor structure of claim 1, wherein the active region comprises a compound of the group consisting of BaSrTiO₃, HfO₂, ZrO₂, and Al2O3.

12. The semiconductor structure of claim 1 wherein the active layer is formed by gas source molecular beam epitaxy.

13. The semiconductor structure of claim 1 wherein the active layer is formed by metal organic chemical vapor deposition.

14. The semiconductor structure of claim 1 wherein the active layer is formed by atomic layer epitaxy.

15. The semiconductor structure of claim 4 wherein the crystalline oxide interface is formed by gas source molecular beam epitaxy.

16. The semiconductor structure of claim 4 wherein the crystalline oxide interface is formed by metal organic chemical vapor deposition.

17. The semiconductor structure of claim 4 wherein the crystalline oxide interface is formed by atomic layer epitaxy.

18. The semiconductor structure of claim 1 wherein the structure is operable as a microelectronic device.

19. The semiconductor structure of claim 1 wherein the structure is operable as an optoelectronic device.

20. A semiconductor structure comprising: a substrate; a Si—Al—O—N region formed over the substrate, and an active region formed over the Si—Al—O—N region.

21. The semiconductor structure of claim 20 wherein the active region comprises a gallium nitride region.

22. The semiconductor structure of claim 20, wherein the active region comprises a compound of the group consisting of GaN, AlGaN, InGaN, AlInGaN, AlN and InN.

23. The semiconductor structure of claim 20, further comprising a crystalline oxide interface formed between the substrate and the SiCAlN region.

24. The semiconductor structure of claim 23 wherein the crystalline oxide interface comprises Si—Al—O—N.

25. The semiconductor structure of claim 20, wherein the substrate comprises a silicon substrate.

26. The semiconductor structure of claim 20, wherein the substrate comprises a silicon carbide substrate.

27. The semiconductor structure of claim 20, wherein the substrate comprises a silicon germanium substrate.

28. The semiconductor structure of claim 20, wherein the active region comprises a compound of the group consisting of BaTiO₃, KNbO₃ and KnbTaO₃.

29. The semiconductor structure of claim 20, wherein the active region comprises a compound of the group consisting of La(x)Sr(1−x)CoO₃ and LaSrTiO₃.

30. The semiconductor structure of claim 20, wherein the active region comprises a compound of the group consisting of BaSrTiO₃, HfO₂, ZrO₂, and Al2O₃.

31. The semiconductor structure of claim 20 wherein the active layer is formed by gas source molecular beam epitaxy.

32. The semiconductor structure of claim 20 wherein the active layer is formed by metal organic chemical vapor deposition.

33. The semiconductor structure of claim 20 wherein the active layer is formed by atomic layer epitaxy.

34. The semiconductor structure of claim 23 wherein the crystalline oxide interface is formed by gas source molecular beam epitaxy.

35. The semiconductor structure of claim 23 wherein the crystalline oxide interface is formed by metal organic chemical vapor deposition.

36. The semiconductor structure of claim 23 wherein the crystalline oxide interface is formed by atomic layer epitaxy.

37. The semiconductor structure of claim 20 wherein the structure is operable as a microelectronic device.

38. The semiconductor structure of claim 20 wherein the structure is operable as an optoelectronic device.
